(19) United States
(12) Patent Application Publication
(10) Pub. No.: US 2026/0120744 A1
(43) Pub. Date: Apr. 30, 2026

(54) SYSTEMS AND METHODS FOR DETERMINING A REFRESH SERVICING RATE BASED ON A REFRESH REQUIREMENT

(71) Applicant: Micron Technology, Inc., Boise, ID (US)

(72) Inventors: Sujeet Ayyapureddi, Boise, ID (US); Gary Howe, Allen, TX (US)

(73) Assignee: Micron Technology, Inc., Boise, ID (US)

(21) Appl. No.: 19/337,747

(22) Filed: Sep. 23, 2025

Related U.S. Application Data
(60) Provisional application No. 63/714,012, filed on Oct. 30, 2024.

(51) Int. Cl. G11C 11/406

(52) U.S. Cl. CPC G11C 11/406

(57) ABSTRACT

Techniques for determining a refresh servicing rate of a memory device are disclosed. A refresh control circuit of the memory device determines that a refresh requirement is not met. The determination can be made, for example, based on a count value indicating refresh operations during a time period, using a shift register, or based on a queue of aggressor addresses. When the refresh requirement is not met, the refresh control circuit increases a refresh servicing rate. Increasing the refresh servicing rate may include applying a multiplier to a number of expected refreshes, or causing performance of background refresh operations until a stopping criterion is met. The refresh requirement may correspond to a number of expected refresh operations (e.g., background refresh operations) during a time period.

### CROSS-REFERENCE TO RELATED APPLICATIONS

This application claims the filing benefit of U.S. Provisional Application No. 63/714,012, filed Oct. 30, 2024. This application is incorporated by reference herein in its entirety and for all purposes.

### BACKGROUND

This disclosure relates generally to semiconductor devices, and more specifically to semiconductor memory devices. Disclosed embodiments relate to volatile memory, such as dynamic random-access memory (DRAM). Information is stored on memory cells as a physical signal, such as a charge on a capacitive element. The memory cells may be organized at the intersection of word lines (rows) and bit lines (columns). Information in the memory cells may decay over time. In order to preserve the integrity of the stored information, the memory device may perform refresh operations to restore the information and prevent information from being lost.

### BRIEF DESCRIPTION OF THE DRAWINGS

FIG. 1 is a block diagram illustrating a memory device according to embodiments of the disclosure.

FIG. 2 is a block diagram illustrating bank logic circuits according to embodiments of the disclosure.

FIG. 3 is a table illustrating refresh servicing rates according to embodiments of the disclosure.

FIG. 4 is a circuit diagram illustrating a shift register according to embodiments of the disclosure.

FIG. 5 is a table illustrating shift register values and corresponding actions according to embodiments of the disclosure.

FIG. 6 is a flow diagram illustrating a process for increasing a refresh servicing rate based on a refresh requirement according to embodiments of the disclosure.

### DETAILED DESCRIPTION

The present disclosure provides descriptions of non-limiting example embodiments and is in no way intended to limit the scope of the disclosure or its applications or uses. In the following detailed description of embodiments of the present technology, reference is made to the accompanying drawings, which form a part hereof and in which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art, so as not to obscure the description of embodiments of the disclosure. The following detailed description is therefore not to be taken as limiting, and the scope of the disclosure is defined only by the appended claims.

A memory device includes a memory array. The memory array includes a number of memory cells at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks.

Information in a memory array may be accessed by performing access operations, such as read or write operations. During an example access operation, a word line may be activated based on a row address. Selected memory cells along that active word line may have their information read from, or written to, based on which bit lines are selected by a column address. The bit lines are coupled to sense amplifiers. The sense amplifiers sense a voltage on the bit line from the memory cells along the active word line and amplify it into a signal in a read operation or drive a voltage to the memory cell along the active word line in a write operation. Each bank may be divided into sections. In some embodiments, a bank is divided into sections, with each section separated from its neighboring sections by a strip of sense amplifiers that are coupled to the bit lines extending into the neighboring sections. Accordingly, the row address may specify which section is being accessed. The sense amplifiers are shared by the neighboring sections, with the sense amplifiers used by one of the neighboring sections during an access operation.

Information in the memory cells decays over time. To prevent information loss, the memory array may be refreshed on a row-by-row basis (e.g., as part of an auto-refresh and/or self-refresh mode), where the memory cells along each row are refreshed periodically to restore the stored information to an initial value. Such refresh operations may be referred to as sequential refresh operations or normal refresh operations, as the memory may use some sequence logic (e.g., a counter) to generate refresh addresses used to determine which word lines are refreshed. Targeted refresh operations may be performed to refresh word lines associated with aggressor word lines.

In some examples, background refresh operations may be performed, which may refresh targeted word lines or word lines identified using sequence logic. In a background refresh operation, a memory device receives an access operation which allows an opportunity for a refresh operation on memory cells other than the memory cells that are accessed for the access operation. For example, the memory determines if a refresh operation is needed and possible, and then performs a refresh operation on a word line in a different section than the section being accessed. The word lines may be active at overlapping periods of time. In this way, refreshes may occur while the memory is being accessed. By contrast, refresh operations performed on their own, such as in response to a refresh command from a controller, may generally be referred to as standalone refresh operations. The use of background refresh operations may help decrease the number of standalone refresh operations. The use of background refresh operations may decrease a downtime of the memory because both access operations and refresh operations may be performed, unlike standalone refresh operations, which may not allow for access operations. A number of background refresh operations performed, if sufficient opportunities exist, may be controlled according to a refresh servicing rate.

A memory device may track how many refresh operations have been performed (e.g., in one or more banks, in one or more sections of a bank, across the memory device) compared to how many refresh operations are expected to be performed in order to generate a refresh deficit count. The refresh deficit count may be used by the memory device to determine whether a refresh operation should be performed. For example, the memory device may be configured to expect at least a threshold number of refresh operations to be performed in a time interval (e.g., one or more refresh intervals (tREFI)), and the refresh deficit count may indicate when the number of actual refresh operations does not satisfy the threshold number. The memory device may use the refresh deficit count to determine when to perform a refresh operation either for background refresh operations or for refresh operations performed responsive to a refresh command. In various examples, the refresh deficit count may be used to set a refresh flag, which may be stored in a mode register of the memory device. For example, when a refresh deficit count (e.g., for a bank, for a section, for all banks) exceeds a threshold value, the memory device may set the refresh flag to indicate that a refresh operation is needed. A memory controller may check the mode register for the status of the refresh flag and issue refresh commands to the memory if necessary. Additionally, or alternatively, the refresh flag may be provided at an active level to indicate that a count of refresh operations is below a threshold value, such as an expected number of refresh operations in a time period.

Embodiments disclosed herein include systems, methods, and apparatuses for determining a refresh servicing rate based on a refresh requirement for a memory device. As used herein, a “refresh servicing rate” can refer to a number of refresh operations to be performed in a time period (e.g., a frequency with which refresh operations are to be performed). In various implementations, the refresh servicing rate can be used to control performance of background refresh operations. For example, a refresh control circuit of a memory device may be configured to cause performance of a number of background refresh operations during a time period, if a sufficient number of background refresh opportunities are available during the time period, and the refresh servicing rate may be expressed as the number divided by the time period.

In disclosed embodiments, the refresh requirement may be a number of refresh operations performed during a time period to ensure that a memory device and/or a portion of a memory device is adequately refreshed. The disclosed technology may use various techniques to determine whether the refresh requirement is met, such as one or more refresh counters, one or more shift registers, and/or one or more aggressor queues, each of which will be further described herein. When the refresh requirement is not met, the refresh control circuit may increase the refresh servicing rate. In various embodiments, the refresh control circuit may increase the refresh servicing rate by increasing a number of background refresh operations that will be performed during a time period, if a sufficient number of background refresh opportunities occurs. Additionally, or alternatively, the refresh control circuit may cause background refresh operations to be performed until a stopping criterion is met. The stopping criterion may be, for example, a shift register value indicating that the memory device is adequately refreshed.

Advantageously, the disclosed technology enables a memory device to catch up on refreshes by increasing a rate at which background refreshes are performed, which may be done without requiring issuance of a refresh command by a memory controller. Additionally, the disclosed technology may track refresh operations and determine refresh servicing rates to help prevent either under-refreshing or over-refreshing of the memory device.

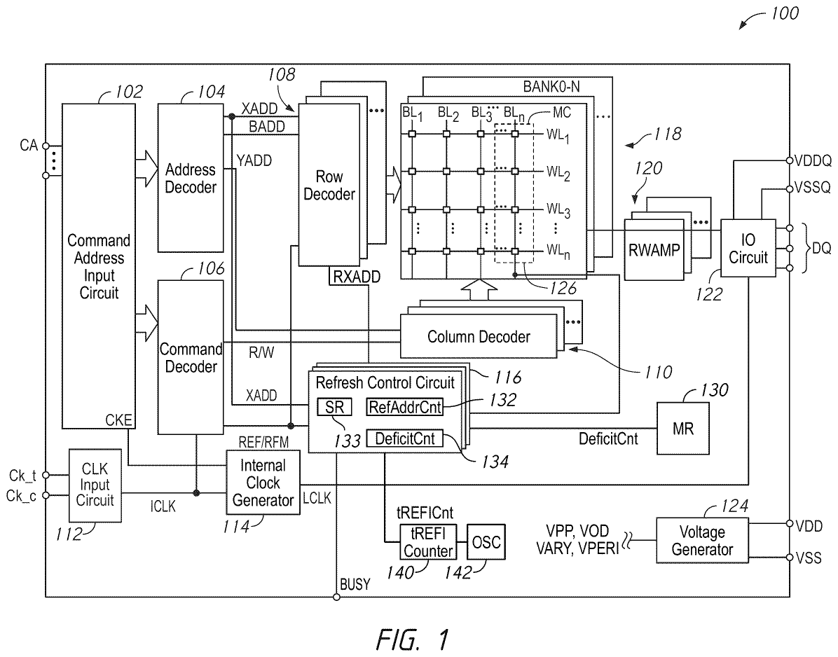

FIG. 1 is a block diagram illustrating a memory device 100 according to embodiments of the disclosure. The memory device 100 may be, for example, a DRAM device integrated on a single semiconductor chip. The memory device 100 may be operated by a memory controller (not shown). In some embodiments, the memory controller and the memory device 100 may be packaged together on a single integrated circuit. In some embodiments, the memory controller and the memory device 100 may be separate. In some embodiments, the memory controller may operate multiple memory devices 100.

The memory device 100 includes a memory array 118. The memory array 118 may be organized into one or more memory banks. In the embodiment of FIG. 1, the memory array 118 is shown as including N+1 memory banks BANK0-BANKN. For example there may be 2, 4, 8, or 16 memory banks. More or fewer banks may be included in the memory array 118 of other embodiments. Each memory bank includes a plurality of word lines WL (rows), a plurality of bit lines BL (columns), and a plurality of memory cells arranged at intersections of the plurality of word lines WL and the plurality of bit lines BL. Each bank is associated with a value of a bank address BADD.

The selection of the word line WL is performed by bank row decoders 108 and the selection of the bit lines BL is performed by a column decoder 110. Certain circuits, such as the bank row decoders 108 and the column decoder 110 may be repeated on a bank-by-bank basis. For example, if there are N+1 banks there may be N+1 bank row decoders 108 and N+1 column decoders 110. Certain other circuits of the memory device 100 may also be repeated on a bank-by-bank basis. For example, each bank may have an associated bank logic region, which includes the circuits associated with that bank.

The bit lines BL are coupled to a respective sense amplifier (SAMP). The sense amplifiers are coupled to local input/output (LIO) and global input/output (GIO) to read/write amplifiers (RWAMP) 120 and through those to the input/output circuits 122 of the memory device 100. During an access operation, the bank row decoder circuits 108 activate a word line specified by the row address. The activated word line couples the memory cells along that word line to the intersecting bit lines. During a read operation, the sense amplifiers amplify the signal along that bit line to a voltage that represents the logical level stored in the memory cell. During a write operation, the sense amplifiers receive a signal indicating a logical level to be written and amplify it onto the bit line and through the bit line to the memory cell. After operations, the bank row decoder circuits 108 pre-charge the word line.

The memory device 100 includes a mode register 130. The mode register includes a number of storage elements, such as latch circuits, organized in registers. The registers store information such as settings of the memory, information about the memory, or combinations thereof. For example, in some embodiments, the mode register 130 stores one or more refresh flags. The refresh flags stored by the mode register 130 may indicate that one or more refresh operations are needed. The memory controller may perform a mode register read (MRR) operation to retrieve information from a specified register or a mode register write (MRW) operation to write information to a specified register. Some registers may be read only to prevent the memory controller from modifying them. Some registers may be updated based on conditions or operations of the memory.

The memory device 100 may employ a plurality of external terminals coupled to the controller. The external terminals include command and address (CA) terminals coupled to the memory controller along a command and address bus to receive commands and addresses. Other external terminals include clock terminals to receive clock signals Ck_t and Ck_c along a clock bus, data terminals DQ to send and receive data along a data bus, and power supply terminals to receive power supply potentials such as VDD, VSS, VDDQ, and VSSQ.

The clock terminals are supplied by the memory controller with external clocks Ck_t and Ck_c that are provided to an input circuit 112. The external clocks may be complementary. The input circuit 112 generates an internal clock ICLK based on the Ck_t and Ck_c. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The CA terminals may be supplied with memory addresses by the memory controller. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include access commands such as an activate command ACT, one or more column commands such as read or write, and pre-charge command PRE, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations.

As part of an example write operation, the CA terminals receive an activate command ACT and a row address. The row decoder 108 activates the specified word line. The row decoder 108 may also activate a word line in a non-selected portion of a respective bank and perform a background refresh operation in one or more rows in the non-selected portion (e.g., based on a background refresh command provided by the refresh control circuit 116), such as to refresh a row identified by the refresh control circuit 116. The CA terminals receive a column command, in this case write, along with a column address. The column decoder couples bit lines specified by the column address YADD to the LIO and GIO lines. The input/output circuit 122 receives data along the data terminals DQ. The data is provided through the RWAMP 120 through the LIO and GIO lines to the specified bit lines. When the controller is done performing operations on the word line, the memory device 100 receives a pre-charge command PRE, and the active word lines are pre-charged.

As part of an example read operation, the CA terminals receive an activate command ACT and a row address. The row decoder 108 activates the specified word line. The row decoder 108 may also activate a word line in a non-selected portion of a respective bank and perform a background refresh operation in one or more rows in the non-selected portion (e.g., based on a background refresh command provided by the refresh control circuit 116), such as to refresh a row identified by the refresh control circuit 116. The CA terminals receive a column command, in this case read, along with a column address. The column decoder couples bit lines specified by the column address YADD to the LIO and GIO lines. The sense amplifiers amplify the signal from the intersecting memory cells along the bit lines to the LIO and GIO lines through the RWAMP 120 to the IO circuit 122. The IO circuit 122 provides the read data to the data terminals DQ. When the memory controller is done performing operations on the word line, the memory device 100 receives a pre-charge command PRE, and the active word lines are pre-charged.

The memory device 100 may also receive commands causing it to carry out standalone refresh operations. For example, the memory controller may issue a refresh command REF or a refresh management command RFM. Responsive to either the REF command or the RFM command, the refresh control circuit 116 may perform one or more refresh operations. As part of a refresh operation, the refresh control circuit 116 issues a refresh address RXADD, and the bank row decoder circuits 108 may refresh one or more word lines based on the refresh address RXADD. The number and type of refresh operations performed may vary based on whether REF or RFM is received. In some embodiments, the refresh control circuit 116 may be repeated on a bank-by-bank basis, similar to the row decoder 108 and the column decoder 110.

The refresh commands REF and RFM are supplied to the refresh control circuit 116. The refresh control circuit 116 supplies one or more refresh addresses RXADD to the row decoder 108, which refreshes one or more word lines WL identified by the refresh row address RXADD. For example, in some embodiments, the refresh control circuit 116 may perform a mix of normal (or sequential) refresh operations and targeted refresh operations responsive to the refresh command REF, and may perform targeted refresh operations responsive to the RFM command RFM. In some embodiments, the refresh control circuit 116 may perform normal refresh operations responsive to REF and targeted refresh commands responsive to RFM.

The refresh control circuit 116 may also perform background refresh operations. When the refresh control circuit 116 determines that there is a refresh opportunity for a bank, the refresh control circuit 116 determines whether or not to perform a refresh operation. For example, the refresh control circuit 116 may determine whether or not to perform a refresh operation based at least in part on if a refresh operation is called for, and if a refresh operation is possible. If the refresh control circuit 116 determines to perform a background refresh operation, the refresh control circuit 116 performs a background refresh operation by generating a refresh address RXADD. The row decoder 108 refreshes a word line associated with RXADD while the word line associated with XADD is being accessed as part of the access operation. In some embodiments, the memory device 100 can also receive a refresh command separate from an access command. Responsive to a refresh command, the refresh control circuit 116 determines whether or not to perform a refresh operation and generates RXADD. However, if a refresh operation is performed responsive to a refresh command, it is a standalone refresh operation on the word line associated with RXADD, and no other different word line is accessed. In some embodiments, multiple word lines may be specified by the refresh address RXADD and the row decoder 108 may refresh all of the word lines associated with RXADD.

The refresh control circuit 116 includes one or more refresh address counter circuits 132, which are used to generate a refresh address RXADD. Each time a refresh operation is performed, the refresh address counter 132 is updated (e.g., incremented) to generate a new value. In this way, the refresh address RXADD counts through the word lines of the bank.

The memory device 100 includes a refresh period counter 140. The memory device 100 may need to perform a certain number of refresh operations in a refresh window. For example, the memory device 100 may need to perform J refresh operations in a refresh window of K ms. In some embodiments, the value of the number of refresh operations (J), the value of the length of the refresh window (K), or combinations thereof, may be set based on values in the mode register 130, such as a refresh setting, a temperature of the memory, or combinations thereof. The memory device 100 sets a refresh interval tREFI based on the average interval between refresh operations in order to perform J operations in K amount of time. For example, tREFI=K/J. The refresh period counter 140 updates a refresh period count tREFIcnt every tREFI amount of time. The refresh period counter 140 may be coupled to an oscillator circuit 142, to a clock signal, or combinations thereof to count time. The tREFI counter 140 may reset the count tREFIcnt to an initial value at power up/reset or when the count reaches J. In this way the refresh interval count may represent a number of refreshes which should have been performed so far in the current refresh window.

The refresh address counter 132 tracks a number of refresh operations that have been performed. The refresh address counter 132 tracks a refresh address count RefAddrCnt, which may be used to generate the refresh address RXADD. In some embodiments, the refresh address count RefAddrCnt may be used as the refresh address RXADD directly. In some embodiments, the refresh control circuit 116 may generate the refresh address RXADD based on the refresh address count RefAddrCnt. The refresh control circuit 116 compares the refresh address count RefAddrCnt to the refresh interval count tREFIcnt. Based on that comparison, the refresh control circuit 116 sets a refresh deficit count DeficitCnt 134. The refresh deficit count DeficitCnt 134 may be stored in storage elements of the memory device 100 such as in register circuits or latch circuits. In some embodiments, if the refresh address count RefAddrCnt is equal to or greater than tREFIcnt, then the refresh deficit count DeficitCnt 134 is set to 0. If the refresh address count RefAddrCnt is less than tREFIcnt, then the refresh deficit count DeficitCnt 134 is set to the difference between tREFIcnt and RefAddrCnt. The refresh deficit count DeficitCnt 134 may be used as a refresh flag, or a refresh flag may be set (e.g., in the mode register 130) based on the refresh deficit count DeficitCnt.

The refresh control circuit 116 uses the refresh deficit count DeficitCnt 134, in part, to determine whether or not to perform a refresh operation. For example, if the deficit count DeficitCnt is 0, then a refresh operation may be skipped, even if the refresh control circuit 116 receives a refresh opportunity. If the deficit count is non-zero, then a refresh operation may be performed when the refresh control circuit 116 is presented with a refresh opportunity. In this manner, each bank or each portion of a bank may be able to determine whether or not to perform a refresh when given the opportunity to do so, either responsive to an access operation or responsive to a refresh command from the memory controller. In some embodiments, a refresh may be performed even if the deficit count is zero. For example, the memory device 100 may perform up to a threshold number of operations even when the deficit count is zero in order to get ahead of the expected number of refreshes.

The refresh control circuit 116 sets a refresh flag in the mode register 130 based on the refresh deficit count DeficitCnt 134. For example, the refresh control circuit 116 may write the refresh deficit count DeficitCnt 134 to the mode register 130, and a deficit count DeficitCnt 134 greater than zero may be considered a refresh flag that is activated. Alternatively, the refresh flag may be a binary value that is set to an active level when the refresh deficit count DeficitCnt 134 is greater than zero. In either embodiment, the memory controller may perform mode register read (MRR) operations to read the refresh flag for each of the banks from the mode register 130.

In various embodiments, the refresh control circuit 116 causes performance of refresh operations (e.g., background refresh operations) according to a refresh servicing rate. For example, a default refresh servicing rate may specify that, when sufficient background refresh opportunities are available, the refresh control circuit 116 will cause performance of 4 background refresh operations during a time period (e.g., one or more tREFI). In various embodiments, the refresh control circuit includes a shift register 133, which is used to determine whether one or more banks of the memory array 118 are adequately refreshed, which determination may be based on the refresh servicing rate. Additionally, or alternatively, the refresh control circuit 116 may use other counters or queues (e.g., an aggressor queue and/or a refresh counter) to determine whether the one or more banks are adequately refreshed. In various examples, the refresh control circuit 116 determines whether a refresh requirement is met based on comparing an actual number of refresh operations (e.g., background refresh operations) performed to an expected number of refresh operations. For example, when the default refresh servicing rate specifies 4 background refresh operations in a time period, the refresh requirement is met if 4 background refresh operations are in fact performed during each of one or more time periods. On the other hand, the refresh requirement is not met when fewer than 4 background refresh operations are performed during one or more time periods. In some examples, the refresh requirement may not be met when there are insufficient opportunities for performing a background refresh operation (e.g., because too few access operations are received during the time period). When the refresh requirement is not met (e.g., as determined using the shift register 133), the refresh control circuit 116 increases the refresh servicing rate. For example, when the refresh servicing rate is not met for M time periods of the last N time periods, the refresh control circuit 116 may apply a multiplier (e.g., 2×, 3×, 4×) to the default refresh servicing rate, such that the refresh control circuit will cause performance of a greater number (e.g., 8, 12, 16) of background refresh operations during a time period (e.g., one or more tREFI). Additionally, or alternatively, when the refresh servicing rate is not met for M time periods of the last N time periods, the refresh control circuit 116 may cause performance of sequential background refresh operations (e.g., at each background refresh opportunity) until a stopping criterion is met. The stopping criterion may be, for example, a determination that the refresh requirement is met, or an indication provided by the shift register 133 that the memory array 118 and/or bank thereof is adequately refreshed. The shift register 133 may provide shift register values, which can be used by the refresh control circuit 116 to determine a refresh servicing rate.

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

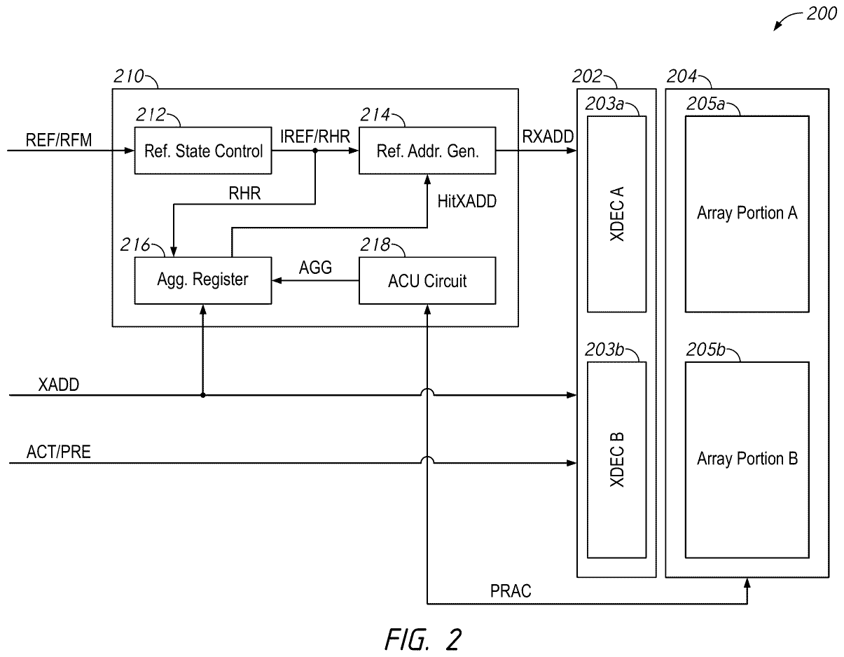

FIG. 2 is a block diagram illustrating bank logic circuits 200 according to embodiments of the disclosure. The bank logic circuits 200 may, in some embodiments, implement a part of a memory device such as 100 of FIG. 1. For example, the bank logic circuits 200 may represent selected circuits in a bank logic region associated with a bank of the memory array 118 of FIG. 1. The bank logic circuits 200 illustrated in FIG. 2 include a refresh control circuit 210 (e.g., 116 of FIG. 1), a row decoder 202 (e.g., 108 of FIG. 1), and a memory bank 204 (e.g., included in 118 of FIG. 1). Certain other circuits that may be part of the bank logic are omitted from the view of FIG. 2 for case of illustration.

The refresh control circuit 210 includes a refresh state control circuit 212, a refresh address generator 214, an aggressor register 216, and an access count update (ACU) logic circuit 218. The refresh state control circuit 212 receives signals such as REF and RFM and determines how many refresh operations should be performed and what types. Additionally, the refresh state control circuit 212 may cause performance of background refresh operations associated with access operations (e.g., according to a refresh servicing rate). The refresh address generator circuit 214 generates the refresh address RXADD. The aggressor register 216 stores one or more identified aggressor addresses HitXADD. The ACU logic circuit 218 updates a per row activation counting PRAC value when a word line is accessed and uses the PRAC value to determine if the word line is an aggressor. The memory bank 204 is split into a portion 205a associated with a row decoder 203a and a portion 205b associated with a row decoder 203b.

The refresh state control circuit 212 receives signals such as REF and RFM and determines how many refresh operations to perform and of what type(s). The refresh state control circuit 212 may also cause performance of background refresh operations, which may be performed without receiving the signals REF and RFM. The refresh state control circuit 212 provides an internal refresh signal IREF to indicate a normal refresh operation and a targeted refresh signal RHR to indicate a targeted refresh operation. In some example implementations, the refresh state control circuit 212 may perform multiple refresh operations for each time REF or RFM is received and/or as part of a background refresh. For example, two, four, six, more or fewer refresh operations may be performed. In some example implementations, the refresh state control circuit 212 may perform only normal refresh operations responsive to REF and perform targeted refresh operations responsive to RFM. In some example implementations the refresh state control circuit 212 may perform a mix of normal and targeted refresh operations responsive to REF and perform targeted refresh operations responsive to RFM.

The refresh address generator 214 generates a refresh address RXADD responsive to IREF, RHR, or combinations thereof. For example, responsive to IREF, indicating a normal refresh address, the refresh address generator circuit 214 generates the refresh address RXADD based on sequence logic. For example, the refresh address generator circuit 214 may include a counter, which increments a value to generate a refresh address for normal refresh operations. Responsive to a targeted refresh operation (e.g., the signal RHR) the refresh address generator 214 uses an aggressor address HitXADD to generate one or more refresh addresses. For example, the refresh addresses may represent the word lines which are adjacent to the word line associated with HitXADD. In some embodiments, during a normal refresh operation multiple word lines may be refreshed, while during a targeted refresh operation a single word line may be refreshed. For example, the refresh address generated for a normal refresh operation may be truncated, and every word line which has an address which shares that truncated portion in common may be refreshed by the row decoder 202. Normal refreshes, targeted refreshes, or both may be performed as part of a background refresh operation.

When a word line is accessed, its associated PRAC value is read out to the ACU logic circuit 218. The row address XADD may indicate if it is associated with the bank portion 205a or the bank portion 205b. For example, a portion select bit of the row address may have a first state if the row address specifies the portion 205a or a second state if the row address specifies the portion 205b. In an example implementation, the bank may be organized such that all of the row addresses that have a most significant bit (MSB) at a logical high are in the portion 205a and all of the row addresses which have a MSB at a logical low are in the portion 205b. Accordingly, the most significant bit may act as the portion select bit.

Responsive to an activate command ACT, the row decoder 203 selected by the portion select bit of the row address activates a word line in the respective portion 205 for the access operation. The row decoder 203 not selected by the portion select bit may also activate a word line to perform a background refresh operation in one or more rows of the unselected portion of the memory bank 204. For example, the refresh state control circuit 212 may selectively cause performance of background refresh operations based on a refresh servicing rate and/or based on whether a refresh requirement is met.

As part of an ACU operation, the ACU logic circuit 218 receives a PRAC value responsive to an activate command ACT. The ACU logic circuit 218 updates the PRAC value, for example by incrementing the PRAC value. If the PRAC value has not crossed a threshold, the updated PRAC value is written back to its original location in the bank 204. If the PRAC value has crossed a threshold, the ACU logic circuit 218 provides an aggressor signal AGG. In some embodiments, responsive to the PRAC value crossing the threshold, the ACU logic circuit 218 resets the PRAC value, for example to an initial value such as 0.

The aggressor register 216 includes a number of ‘slots’ which may be used to store aggressor addresses. For example, each slot may include a number of latch circuits the length of a row address. Responsive to the aggressor signal AGG, the register 216 adds the current row address XADD to the register. The register 216 may act as a first-in, first-out (FIFO) register in some embodiments.

As discussed herein, background refresh enables each portion 205 to be refreshed when the other portion 205 is being accessed. A number of background refresh operations performed during a time period is controlled according to a refresh servicing rate determined by the refresh control circuit 210. In various embodiments, there may be 64 ACT slots during an interval tREFI, each slot providing an opportunity for a background refresh operation. The refresh servicing rate may specify a number of the ACT slots that will be used to perform a background refresh operation if a sufficient number of access commands are received during the interval tREFI. For example, a refresh servicing rate of 4 may specify that 4 of the ACT slots will be used to perform background refresh operations, if at least 4 access operations are received during the interval tREFI. But, if fewer than 4 access operations are received during the interval tREFI, then an insufficient number of background refresh operations will be performed to meet the number of refresh operations specified by the refresh servicing rate. If an insufficient number of refresh operations are performed across one or more of the intervals tREFI, the refresh control circuit 210 will increase the refresh servicing rate to cause performance of more and/or more frequent background refresh operations when access operations are received. While an example refresh servicing rate of 4 background refresh operations per tREFI is described for illustrative purposes, other refresh servicing rates may be used (e.g., as a default refresh servicing rate), and more or fewer ACT slots per tREFI may be provided in other embodiments.

In various embodiments, the refresh control circuit 210 uses one or more counters to determine whether an actual number of background refresh operations performed during a time period satisfies a refresh requirement specified by the refresh servicing rate. Additionally, or alternatively, the refresh control circuit 210 may use a shift register (e.g., 133 of FIG. 1) to determine whether the refresh requirement is met. In these and other embodiments, one or more refresh requirements may be based on a number of addresses in the aggressor register 216. For example, when a number of identified aggressor addresses HitXADD or associated refresh addresses exceeds a threshold value, the refresh control circuit 210 may determine that a refresh requirement is not met, and the refresh control circuit 210 may respond by increasing the refresh servicing rate.

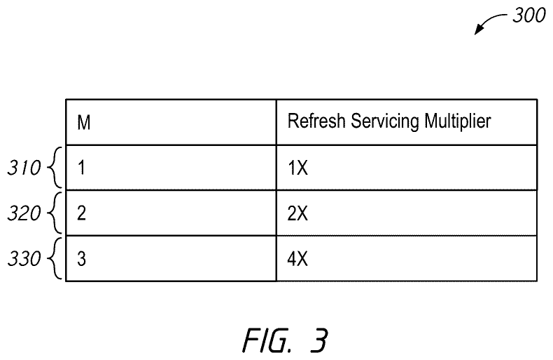

FIG. 3 is a table 300 illustrating refresh servicing rates according to embodiments of the disclosure.

In various embodiments, a refresh control circuit (e.g., 116 of FIG. 1) of a memory device (e.g., 100 of FIG. 1) applies a default refresh servicing rate R, which specifies a number of background refresh operations that will be performed during a time period T for access operations that are received by the memory device and provide corresponding background refresh opportunities. The time period T may be one or more intervals tREFI. The refresh control circuit determines, for each time period T, whether at least R background refresh operations have been performed. If at least R background refresh operations have been performed during the time period T, then the refresh control circuit determines that a refresh requirement for the memory device has been met for that time period T. If fewer than R background refresh operations have been performed during the time period T, then the refresh control circuit determines that the refresh requirement for the memory device has not been met for that time period T.

The refresh control circuit may adjust the refresh servicing rate R based on a number M of refresh time periods T of the last N time periods T during which the refresh requirement was not met.

In a first row 310 of the table 300, M=1, such that the refresh control circuit has determined that the refresh requirement for the memory device was not met in 1 time period T of the last N time periods T. For example, assuming N=8, the first row 310 illustrates a situation in which the refresh requirement specified by the default refresh servicing rate R was not met for 1 of the last 8 time periods T. When M=1, the refresh control circuit may apply a refresh servicing multiplier of 1× to the default refresh servicing rate R, such that a refresh servicing rate of 1R is applied in one or more subsequent time periods T. In other words, in the illustrated example, the default refresh servicing rate R continues to be applied when the refresh requirement has not been met in only 1 of the last 8 time periods T.

In a second row 320 of the table 300, M=2, such that the refresh control circuit has determined that the refresh requirement for the memory device was not met in 2 time periods T of the last N time periods T. For example, assuming N=8, the second row 320 illustrates a situation in which the refresh requirement specified by the default refresh servicing rate R was not met for 2 of the last 8 time periods T. When M=2, the refresh control circuit may apply a refresh servicing multiplier of 2× to the default refresh servicing rate R, such that a refresh servicing rate of 2R is applied in one or more subsequent time periods T. In other words, in the illustrated example, an increased refresh servicing rate of 2R is applied when the refresh requirement has not been met in 2 of the last 8 time periods T. A a result, 2R background refresh operations will be performed in each subsequent time period T until the refresh servicing rate is increased or decreased.

In a third row 330 of the table 300, M=4, such that the refresh control circuit has determined that the refresh requirement for the memory device was not met in 4 time periods T of the last N time periods T. For example, assuming N=8, the third row 330 illustrates a situation in which the refresh requirement specified by the default refresh servicing rate R was not met for 4 of the last 8 time periods T. When M=4, the refresh control circuit may apply a refresh servicing multiplier of 4× to the default refresh servicing rate R. As a result, a refresh servicing rate of 4R is applied in one or more subsequent time periods T. In other words, in the illustrated example, an increased refresh servicing rate of 4R is applied when the refresh requirement has not been met in 4 of the last 8 time periods T, and 4R background refresh operations will be performed in each subsequent time period T until the refresh servicing rate is increased or decreased.

In various embodiments, the increased refresh servicing rates illustrated with reference to the second row 320 and the third row 330 may continue to be applied until a stopping criterion is met. For example, the increased refresh servicing rates may be applied until M is less than or equal to 1, such that the refresh requirement has been met in at least N−1 of the last N time periods.

While example values of R, T, M, and N are discussed herein for illustrative purposes, it will be appreciated that other values can be used while maintaining a similar functionality. Additionally, more or fewer refresh servicing multipliers may be used.

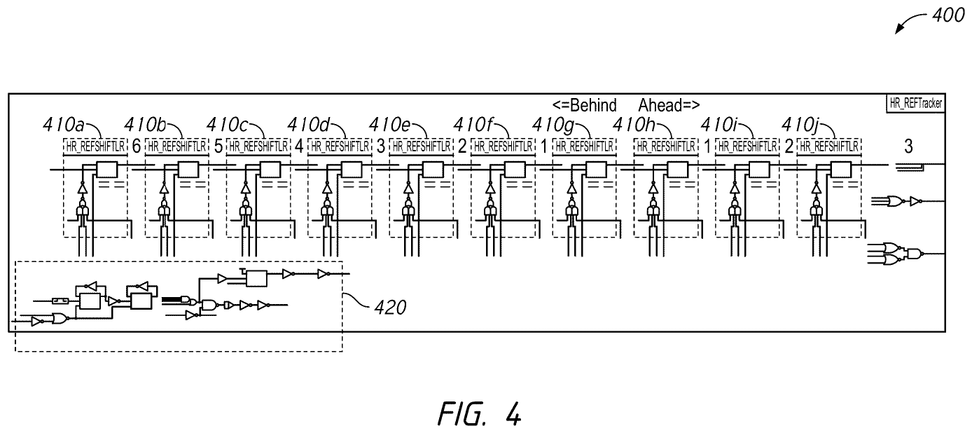

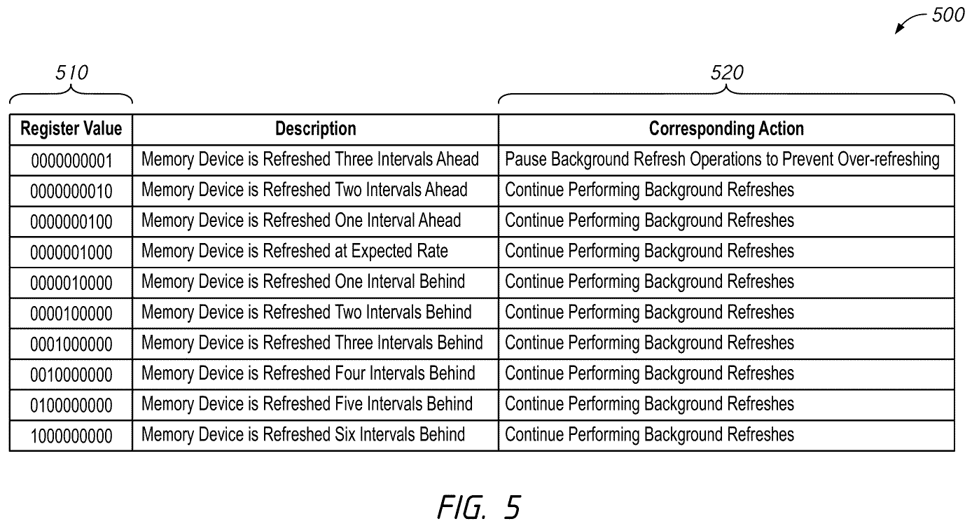

FIG. 4 is a circuit diagram illustrating a shift register 400 according to embodiments of the disclosure. The shift register 400 may be included in a refresh control circuit of a memory device. In some embodiments of the disclosure, the shift register 400 may be included in the shift register 133 of FIG. 1. The shift register 400 is configured to provide shift register values (e.g., as illustrated with reference to FIG. 5) that are used to control a refresh servicing rate, such as a rate at which background refresh operations are performed, based on comparing an actual number of refresh operations to an expected number of refresh operations. For example, the refresh control circuit may determine a current state of the shift register 400 as a binary shift register value, and the refresh control circuit may determine a refresh servicing rate based on the current state of the shift register 400.

The shift register 400 comprises a plurality of shift stages 410 and a counting circuit 420. In the depicted example, ten shift stages 410a-j are illustrated. More or fewer shift stages 410 can be used in other embodiments. At a given time, one shift stage 410 of the plurality of shift stages 410 is active to provide a signal at an active level, while the remaining shift stages 410 are inactive and provide a respective signal at an inactive level. By determining which shift stage 410 of the plurality of shift stages 410 is active (e.g., expressed as a shift register value), the refresh control circuit may determine whether the memory device is “ahead” of an expected number of refresh operations, “behind” the expected number of refresh operations, or neither ahead nor behind the expected number of refresh operations. The memory device is “ahead” when an actual number of refresh operations exceeds the expected number of refresh operations. The memory device is “behind” when the actual number of refresh operations is below the expected number of refresh operations. The memory device is neither ahead nor behind when the actual number of refresh operations equals the expected number of refresh operations. The determination of whether the memory device is ahead, behind, or neither ahead nor behind, can be made for one or more time periods T, which may be based on tREFI.

The shift register 400 uses the counting circuit 420 to determine which shift stage 410 to activate (e.g., relative to a currently activated shift stage 410). The counting circuit 420 may be a counter configured to count up to an expected number of refreshes in a time period T. For example, the counting circuit 420 can comprise a by-four counter in implementations where the shift register 400 is configured to expect four background refresh operations (e.g., four refreshed rows) during a time period T. In other embodiments, the counting circuit may be configured based on a different number of background refreshes, such as 2, 8, 16, or another number. In some examples, the shift register 400 may be initialized to a default state, such that the shift stage 410g is activated to provide the signal at the active level and the remaining shift stages 410 are inactive, which indicates that the memory device is neither ahead nor behind, relative to the expected number of refresh operations.

Thereafter, for subsequent time periods T, the counting circuit 420 tracks a number of refresh operations (e.g., background refresh operations) that are actually performed. When the actual number of refresh operations equals the expected number of refresh operations, the counting circuit 420 will not cause any change to which shift stage 410 is activated. For example, when the shift stage 410g is activated, and the counting circuit 420 determines that the expected number of refresh operations has been performed for a time period T, the shift stage 410g will remain activated to indicate that the expected number of refresh operations has been performed. In other words, the shift register 400 will neither shift left nor shift right.

When the actual number of refresh operations exceeds the expected number of refresh operations (e.g., by at least a threshold amount), the counting circuit 420 may cause the shift register 400 to “shift right” by deactivating a currently active shift stage 410 and activating the shift stage 410 immediately to the right. For example, when the shift stage 410g is active, and the counting circuit 420 detects that the actual number of refresh operations during the time period T exceeds the expected number of refresh operations during the time period T by four, the counting circuit 420 will cause the currently active shift stage 410g to be deactivated and cause the shift stage 410h immediately to the right to be activated shift stage. This indicates that the memory device is now “ahead” of the expected number of refresh operations by four rows.

When the actual number of refresh operations during the time period T is less than the expected number of refresh operations, the counting circuit 420 may cause the shift register 400 to “shift left” by deactivating the currently active shift stage 410 and activating the shift stage 410 immediately to the left. For example, when the active circuit 410g is active, and the counting circuit 420 detects that the actual number of refresh operations during the time period T is less than the expected number of refresh operations during the time period T, the counting circuit will cause the currently active shift stage 410g to be deactivated and cause the shift stage 410f immediately to the left to be activated shift stage. This indicates that the memory device is now “behind” the expected number of refresh operations (e.g., by a number of refresh operations or rows between one and four).

The foregoing operations can be repeated for any number of time periods T, and the shift register 400 may shift left or right depending on an actual number of refresh operations (e.g., background refresh operations) performed in successive time periods T. For example, the shift register 400 may shift left when a memory is unable to perform at least an expected number of background refresh operations, such as when insufficient refresh operations access operations are received by the memory. The shift register 400 may shift right when more than the expected number of background refresh operations are performed thereby causing an excess number of background refresh operations, such as when more than enough access operations are received by the memory.

The activation state of the shift stages 410 may be expressed as a shift register value, which indicates whether the memory device is ahead, behind, or neither ahead nor behind relative to an expected number of refresh operations. The shift register value can be used (e.g., by the refresh control circuit) to determine a refresh servicing rate. In various embodiments, the refresh control circuit may set the refresh servicing rate to cause performance of background refresh operations at every opportunity until a stopping criterion is met, such as until the memory device is ahead by 12 refresh operations or rows, as indicated by activation of the shift stage 410j. When the stopping criterion is met, the refresh control circuit may pause or slow performance of background refresh operations. In various embodiments, the refresh servicing rate may also be adjusted when the memory device is behind by at least a threshold number of refresh operations and/or other actions may be taken to cause performance of more refresh operations. For example, the refresh control circuit may cause performance of background refresh operations at a default refresh servicing rate when the shift register 400 indicates that the actual number of refresh operations equals the expected number of refresh operations, and the refresh control circuit may cause performance of background refresh operations at an increased refresh servicing rate greater than the default refresh servicing rate when the shift register 400 indicates that the actual number of refresh operations is less than the expected number of refresh operations. In some implementations, the refresh servicing rate may be adjusted proportionally to an amount that the memory device is ahead or behind relative to an expected number of refresh operations, such that refresh operations are performed more frequently when the memory device is farther behind and less frequently when the memory device is farther ahead.

FIG. 5 is a table 500 illustrating shift register values 510 and corresponding actions 520 according to embodiments of the disclosure. The shift register values 510 indicate whether a memory device is ahead, behind, or neither ahead nor behind relative to an expected number of refresh operations (e.g., background refresh operations) for one or more time periods T. The corresponding actions 520 may relate to refresh servicing rates determined by a refresh control circuit of the memory device based on the shift register values 510. The shift register values 510 may be determined by and/or retrieved from a shift register. For example, in some embodiments of the disclosure the shift register values 510 are determined by and/or retrieved from a shift register 133 of FIG. 1 and/or shift register 400 of FIG. 4.

A shift register value 510 of 0000001000 may indicate that the memory device is being refreshed at an expected rate (e.g., that an actual number of refresh operations during the previous N time periods is equal to an expected number of refresh operations during the previous N time periods). For example, the shift register value 510 of 0000001000 may correspond to activation of the shift stage 410g of FIG. 4. As described with reference to FIG. 4, the shift register may be initiated to a default state (e.g., a shift register value of 0000001000), and the shift register may shift left or right, or maintain a current state, based on comparing an actual number of refresh operations to an expected number of refresh operations during successive time periods T.

For example, when an actual number of refresh operations during a time period T exceeds an expected number of refresh operations during the time period T by at least a threshold amount (e.g., by four) the shift register may shift right, which changes the shift register value 510 from 0000001000 to 0000000100 (e.g., corresponding to activation of the shift stage 410h of FIG. 4). If the actual number of refresh operations continues to exceed the expected number of refresh operations during one or more subsequent time periods T, then the shift register may continue to shift right, which changes the shift register value 510 from 0000000010 (e.g., corresponding to activation of the shift stage 410i of FIG. 4) for a next time period, and 0000000001 (e.g., corresponding to activation of the shift stage 410j of FIG. 4) for the time period after that.

On the other hand, when the actual number of refresh operations during one or more time periods T is less than the expected number of refresh operations during the time period T, the shift register may shift left, which changes the shift register value 510 from 0000001000 to 0000010000 (e.g., corresponding to activation of 410f of FIG. 4). If the actual number of refresh operations continues to be less than the expected number of refresh operations, then the shift register may continue to shift left for successive time periods T, which gradually changes the shift register value 510 (e.g., 0000100000 corresponding to activation of 410e of FIG. 4, 0001000000 corresponding to activation of 410d of FIG. 4, 0010000000 corresponding to activation of 410c of FIG. 4, 0100000000 corresponding to activation of 410b of FIG. 4, and 1000000000 corresponding to activation of 410a of FIG. 4, for successive time periods T during which fewer than an expected number of refresh operations are performed).

As described herein, the shift register value 510 may shift left, shift right, or stay the same relative to a current shift register value 510 based on comparing the actual number of refresh operations to the expected number of refresh operations for one or more time periods T.

The shift register values 510 can be used by a refresh control circuit to cause performance of respective actions 520 related to a refresh servicing rate. For example, when the shift register value 510 is 0000000001, the refresh control circuit may pause or reduce the frequency of refresh operations (e.g., background refresh operations). For other shift register values 510, the refresh control circuit may cause performance of refresh operations (e.g., background refresh operations) at every opportunity. Additionally, or alternatively, the refresh control circuit may cause performance of refresh operations at a default rate for a first range of shift register values 510 (e.g., 0001000000 to 0000001000), a reduced rate for a second range of shift register values 510 (e.g., 0000000100 to 0000000001), and an increased rate for a third range of shift register values 510 (e.g., 1000000000 to 0010000000).

While example operations are described herein related to use of a shift register and shift register values 510, it will be appreciated that these operations can be modified while maintaining a similar functionality. For example, different shift register values 510 (e.g., more or fewer shift register values 510) can be used, and different refresh servicing rates can be applied based on shift register values 510.

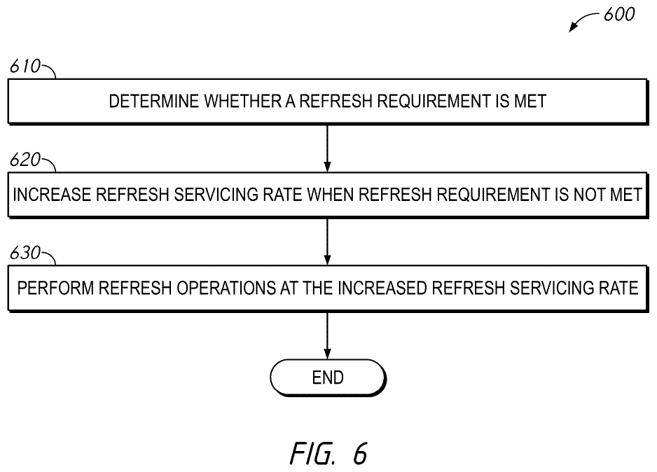

FIG. 6 is a flow diagram illustrating a process 600 for increasing a refresh servicing rate based on a refresh requirement according to embodiments of the disclosure. The process 600 may be performed using at least a portion of a memory device (e.g., 100 of FIG. 1). For example, at least a portion of the process 600 may be performed by a refresh control circuit (e.g., 116 of FIG. 1).

The process 600 begins at block 610, where it is determined whether a refresh requirement for one or more banks of a memory device has been met during one or more time periods. For example, a refresh control circuit may determine whether an actual number of background refresh operations performed in a bank has met an expected number of background refresh operations during one or more time periods. In various embodiments, the determination can be made using a shift register (e.g., 400 of FIG. 4) and/or based on a shift register value (e.g., 510 of FIG. 5). Additionally, or alternatively, the determination can be made based on an aggressor queue. For example, when a number of aggressor addresses and/or an associated number of victim addresses exceeds a threshold value, it can be determined that the refresh requirement is not met. The aggressor queue can be stored in an aggressor register (e.g., 216 of FIG. 2).

The process 600 proceeds to block 620, where the refresh servicing rate is increased when it is determined that the refresh servicing requirement is not met. For example, a multiplier may be applied to a default refresh servicing rate based on a number M of time periods T of the last N time periods T during which an actual number of background refresh operations was less than an expected number of background refresh operations, as described with reference to the table 300 of FIG. 3. Additionally, or alternatively, background refresh operations may be performed sequentially with each background refresh opportunity or according to a specified frequency (e.g., every other opportunity, every third opportunity).

The process 600 proceeds to block 630, where refresh operations are performed according to the increased refresh servicing rate until a stopping criterion is met. Various stopping criteria may be used to determine when to stop applying the increased refresh servicing rate (e.g., to return to the default refresh servicing rate or to pause background refresh operations). For example, the refresh servicing rate can be reduced and/or returned to a default rate when the refresh requirement is met for at least M time periods of the last N time periods. Additionally, or alternatively, the refresh servicing rate can be reduced and/or returned to a default rate when a number of addresses in the aggressor queue is below a threshold. Additionally, or alternatively, the refresh servicing rate may be decreased and/or refresh operations may be paused based on a shift register value (e.g., indicating that the memory device is ahead by at least a threshold amount relative to an expected number of refreshes).

It will be appreciated that operations of the process 600 can be added, omitted, combined, repeated, or performed in parallel while maintaining a similar functionality.

It is to be appreciated that any one of the examples, embodiments or processes described herein may be combined with one or more other examples, embodiments and/or processes or be separated and/or performed amongst separate devices or device portions in accordance with the present systems, devices, and methods.

Finally, the above discussion is intended to be merely illustrative of the present system and should not be construed as limiting the appended claims to any particular embodiment or group of embodiments. Thus, while the present systems, apparatuses, and methods have been described in particular detail with reference to example embodiments, it should also be appreciated that modifications and alternative embodiments may be devised by those having ordinary skill in the art without departing from the broader and intended spirit and scope of the present technology as set forth in the claims that follow. Accordingly, the present disclosure is to be regarded in an illustrative manner and is not intended to limit the scope of the appended claims.

What is claimed is:

1. An apparatus comprising:
a memory array comprising a plurality of memory cells; and
a refresh control circuit configured to cause performance of refresh operations at the memory array, wherein the refresh control circuit is configured to determine a refresh servicing rate based on a refresh count.

2. The apparatus of claim 1, further comprising:
a shift register configured to provide the refresh count, wherein the refresh count indicates a number of refreshes relative to an expected number of refreshes.

3. The apparatus of claim 1, wherein the refresh servicing rate comprises an expected number of refresh operations during a time interval, and wherein the time interval is based on a refresh interval.

4. The apparatus of claim 1, wherein the refresh control circuit is configured to apply the refresh servicing rate to cause performance of background refresh operations.

5. The apparatus of claim 1, wherein the refresh servicing rate comprises a multiplier.

6. The apparatus of claim 1, wherein the refresh servicing rate has a first value when the refresh count is below a threshold value and a second value lower than the first value when the refresh count meets or exceeds the threshold value.

7. The apparatus of claim 1, wherein the refresh control circuit is configured to pause performance of the refresh operations when an actual refresh rate exceeds the refresh servicing rate.

8. A system comprising:
a memory controller; and
a memory device comprising a memory array and a refresh control circuit configured to determine whether a refresh requirement for the memory array is met and increase a refresh servicing rate for the memory array when the refresh requirement is not met.

9. The system of claim 8, wherein the refresh control circuit comprises a shift register configured to compare an actual number of refreshes to an expected number of refreshes.

10. The system of claim 9, wherein the refresh control circuit is configured to pause performance of background refresh operations when the actual number of refreshes exceeds the expected number of refreshes by a threshold value.

11. The system of claim 8, wherein the refresh control circuit is configured to determine whether the refresh requirement is met based at least in part on a number of aggressor addresses in an aggressor queue.

12. The system of claim 8, wherein the refresh servicing rate is applied to cause performance of a corresponding number of background refresh operations during a time interval.

13. The system of claim 12, wherein the time interval is based on a refresh interval.

14. The system of claim 8, wherein the refresh control circuit is configured to determine whether the refresh requirement is met using a refresh counter.

15. The system of claim 8, wherein the refresh servicing rate comprises a multiplier applied to a default refresh servicing rate.

16. A method comprising:
storing, by a memory device, a refresh count;
determining, by the memory device, a refresh servicing rate based on the refresh count; and
causing performance of refresh operations according to the refresh servicing rate.

17. The method of claim 16, wherein the refresh servicing rate comprises an expected number of refresh operations during a time interval, and wherein the time interval is based on a refresh interval.

18. The method of claim 16, wherein the refresh operations comprise background refresh operations.

19. The method of claim 16, wherein the refresh servicing rate comprises a multiplier applied to a default refresh servicing rate.

20. A method comprising:
determining, by a refresh control circuit of a memory device, that a refresh requirement of the memory device is not met;
increasing, responsive to the determination that the refresh requirement is not met, a refresh servicing rate for the memory; and
causing performance, by the refresh control circuit, of refresh operations according to the refresh servicing rate.

21. The method of claim 20, wherein the refresh operations comprise background refresh operations.

22. The method of claim 20, wherein the refresh control circuit determines that the refresh requirement is not met using a shift register that compares an actual number of refresh operations to an expected number of refresh operations.

23. The method of claim 20, wherein the refresh control circuit determines that the refresh requirement is not met based at least in part on an aggressor queue comprising row addresses identified based on detecting aggressor rows of the memory device.

24. The method of claim 20, wherein the refresh control circuit determines that the refresh requirement is not met using a refresh counter.
